(19) United States
(12) Patent Application Publication
(10) Pub. No.: US 2025/0239832 A1
(43) Pub. Date: Jul. 24, 2025

(54) LIGHT EMITTING DEVICE, LIGHT EMITTING APPARATUS, AND MEASURING APPARATUS

(71) Applicant: FUJIFILM BUSINESS INNOVATION CORP., Tokyo (JP)

(72) Inventor: Daisuke IGUCHI, Kanagawa (JP)

(73) Assignee: FUJIFILM BUSINESS INNOVATION CORP., Tokyo (JP)

(21) Appl. No.: 18/767,469

(22) Filed: Jul. 9, 2024

(30) Foreign Application Priority Data
Jan. 24, 2024 (JP) 2024-009049

(51) Int. Cl. H01S 5/026; G01S 7/481; G01S 17/894; H01S 5/183

(52) U.S. Cl. CPC H01S 5/0261; G01S 7/4815; G01S 17/894; H01S 5/183

(57) ABSTRACT

A light emitting device includes plural light emitting blocks, each including a light emitting element and a setting element that sets the light emitting element in a state of being able to be turned on, and a discharge path that includes a discharge element capable of controlling discharge in a case where the light emitting element is turned off and through which charges accumulated in a case where the light emitting element is turned on are discharged, in which the plural light emitting blocks and the discharge path are electrically connected in parallel.

### CROSS-REFERENCE TO RELATED APPLICATIONS

This application is based on and claims priority under 35 USC 119 from Japanese Patent Application No. 2024-009049 filed Jan. 24, 2024.

### BACKGROUND

### (i) Technical Field

The present invention relates to a light emitting device, a light emitting apparatus, and a measuring apparatus.

### (ii) Related Art

JP2023-112924A discloses a light emitting apparatus including a light emitting unit that includes a light emitting element, a driving unit that includes a first element connected to a cathode electrode provided on a cathode side of the light emitting element and supplies a current for causing light emission to perform driving, and a capacity portion that is provided in parallel with a current path for causing light emission between the cathode electrode and an anode electrode provided on an anode side of the light emitting element.

### SUMMARY

In recent years, a time of flight (ToF) sensor has become mainstream as a distance measuring sensor used for object recognition or the like, and a light emitting device in which light emitting elements such as vertical cavity surface emitting lasers (VCSELs) are integrated is used as a light source of the ToF sensor.

A ToF sensor used in an application of a mobile device such as a smartphone is required to achieve both high spatial resolution and power saving. The light emitting element as the light source is required to have a rising time/falling time of less than 1 ns. In a case where the light source includes a plurality of blocks of light emitting elements and performs block irradiation for turning on a selected block, power saving can be achieved as compared with a case where all light emitting elements are simultaneously turned on. In the block irradiation, the blocks that are not selected constitute a capacity and charges are accumulated. The falling time of the light emitting element is increased due to the discharge of the charges.

Aspects of non-limiting embodiments of the present disclosure relate to a light emitting device, a light emitting apparatus, and a measuring apparatus that have a short falling time of a light emitting element shorter as compared with a case where a discharge path is not provided.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting device including a plurality of light emitting blocks, each including a light emitting element and a setting element that sets the light emitting element in a state of being able to be turned on, and a discharge path that includes a discharge element capable of controlling discharge in a case where the light emitting element is turned off and through which charges accumulated in a case where the light emitting element is turned on are discharged, in which the plurality of light emitting blocks and the discharge path are electrically connected in parallel.

### BRIEF DESCRIPTION OF THE DRAWINGS

Exemplary embodiment(s) of the present invention will be described in detail based on the following figures, wherein:

FIG. 1 is a block diagram showing a schematic configuration of a measuring apparatus that measures a three-dimensional shape and the like of a measurement target object by a ToF method to which a first exemplary embodiment is applied;

FIG. 2 is a diagram showing an example of a planar shape of a light emitting device to which the first exemplary embodiment is applied;

FIG. 3 is a cross-sectional view showing an example of a cross-sectional structure of the light emitting device to which the first exemplary embodiment is applied;

FIG. 4 shows an equivalent circuit of the light emitting device to which the first exemplary embodiment is applied;

FIGS. 5A and 5B show an equivalent circuit for describing a light emitting apparatus using a light emitting device that does not include a discharge thyristor and to which the first exemplary embodiment is not applied, in which FIG. 5A shows an equivalent circuit showing 24 light emitting blocks, and FIG. 5B shows an equivalent circuit in a case where one light emitting block is turned on and other light emitting blocks are set in a turned-off state;

FIGS. 6A and 6B show an equivalent circuit for describing an influence of a parallel capacitance, in which FIG. 6A shows a light emitting apparatus using a light emitting device including one light emitting block, and FIG. 6B shows a light emitting apparatus using a light emitting device including 24 light emitting blocks;

FIG. 7 shows a result of simulating a current flowing to a VCSEL by the equivalent circuit for describing the influence of the parallel capacitance;

FIG. 8 shows an equivalent circuit of the light emitting apparatus using a light emitting device including a discharge thyristor, to which the first exemplary embodiment is applied;

FIGS. 9A and 9B are timing charts for describing a turn-on control signal and a discharge control signal used in the simulation, in which FIG. 9A shows the turn-on control signal, and FIG. 9B shows the discharge control signal;

FIG. 10 shows a result of simulating a current flowing to a VCSEL in the light emitting apparatus using the light emitting device including the discharge thyristor, to which the first exemplary embodiment is applied;

FIG. 11 shows an equivalent circuit for describing a light emitting apparatus (Comparative Example) including a switch;

FIG. 12 shows a result of simulating a current flowing to a VCSEL in the light emitting apparatus (Example) using the light emitting device including the discharge thyristor and the light emitting apparatus (Comparative Example) including the switch;

FIG. 13 is a cross-sectional view showing a cross-sectional shape of a light emitting device to which a second exemplary embodiment is applied; and

FIG. 14 shows an equivalent circuit of a light emitting apparatus using the light emitting device to which the second exemplary embodiment is applied.

### DETAILED DESCRIPTION

Hereinafter, exemplary embodiments of the present invention will be described in detail with reference to the accompanying drawings. The same reference numeral may be used for members having the similar function. In addition, reference numerals may be given to some components, and the reference numerals may not be given to the similar components.

A ToF sensor used for object recognition or the like is an example of a measuring apparatus that measures a three-dimensional shape of a measurement target object by a distance to the measurement target object measured based on the ToF method. Hereinafter, the ToF sensor will be described as a measuring apparatus. A measuring apparatus that measures a three-dimensional shape or the like by the ToF method measures a distance to a measurement target object from a timing at which light is emitted from a light emitting apparatus provided in the measuring apparatus to a timing at which the emitted light is reflected by a measurement target object and then is received by a three-dimensional sensor (may be referred to as a “3D sensor” below) provided in the measuring apparatus. Then, the measuring apparatus measures the three-dimensional shape. The 3D sensor is an example of a light receiving unit.

The ToF method includes an indirect ToF (iToF) method in which a time is measured from a difference between a phase of radiated light and a phase of received light, and a direct ToF (dToF) method in which a time from light radiation to reception of light is directly measured. In the ToF method, it is required that the rising/falling of the emitted light is steep, in other words, the rising time/falling time is short. In particular, the direct ToF method is required to have a shorter rising time/falling time than a rising time/falling time of the indirect ToF method. Here, the direct ToF method and the indirect ToF method will be described as the ToF method without distinction.

The three-dimensional shape of the measurement target object may be referred to as a “three-dimensional image” or a “3D shape”. Measurement of a three-dimensional shape may be referred to as “three-dimensional measurement”, “3D measurement”, or “3D sensing” below.

Hereinafter, configurations, functions, methods, and the like described as exemplary embodiments of the present invention can be applied to face recognition, augmented reality (AR), other three-dimensional measurement, and the like in an information processing apparatus such as a mobile device.

In addition, the configurations, functions, methods, and the like described as the exemplary embodiments of the present invention can be used not only for three-dimensional measurement but also for simply measuring a distance to a measurement target object.

### First Exemplary Embodiment

### Measuring Apparatus 100

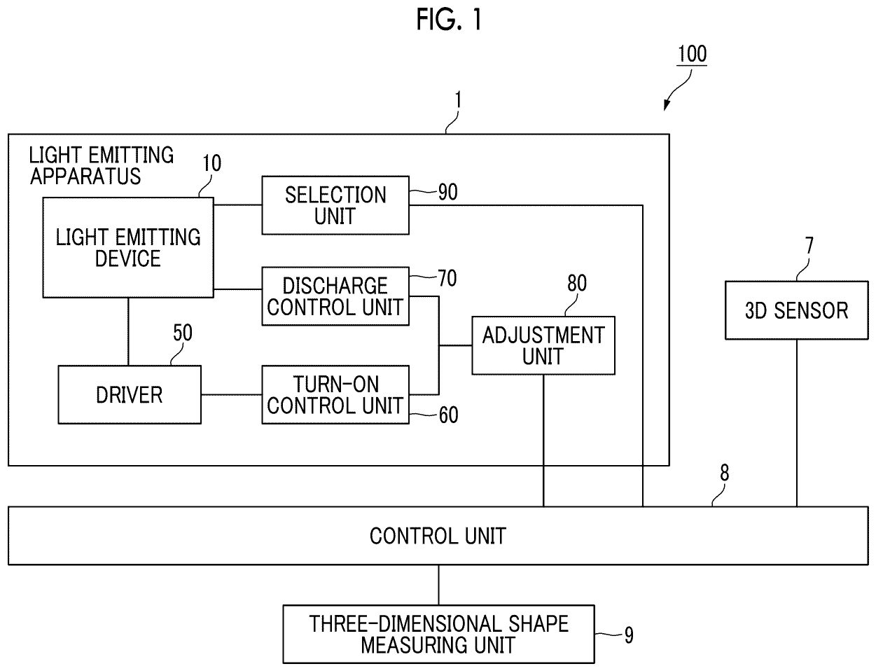

FIG. 1 is a block diagram showing a schematic configuration of a measuring apparatus 100 that measures a three-dimensional shape and the like of a measurement target object by a ToF method to which a first exemplary embodiment is applied. The measuring apparatus 100 includes a light emitting apparatus 1 and a 3D sensor 7. The measuring apparatus 100 may include a control unit 8 that controls the light emitting apparatus 1 and the 3D sensor 7. Further, the measuring apparatus 100 may include a three-dimensional shape measuring unit 9 that measures a three-dimensional shape or the like of a measurement target object based on a distance to the measurement target object.

The light emitting apparatus 1 includes a light emitting device 10, a driver 50, a turn-on control unit 60, a discharge control unit 70, an adjustment unit 80, and a selection unit 90.

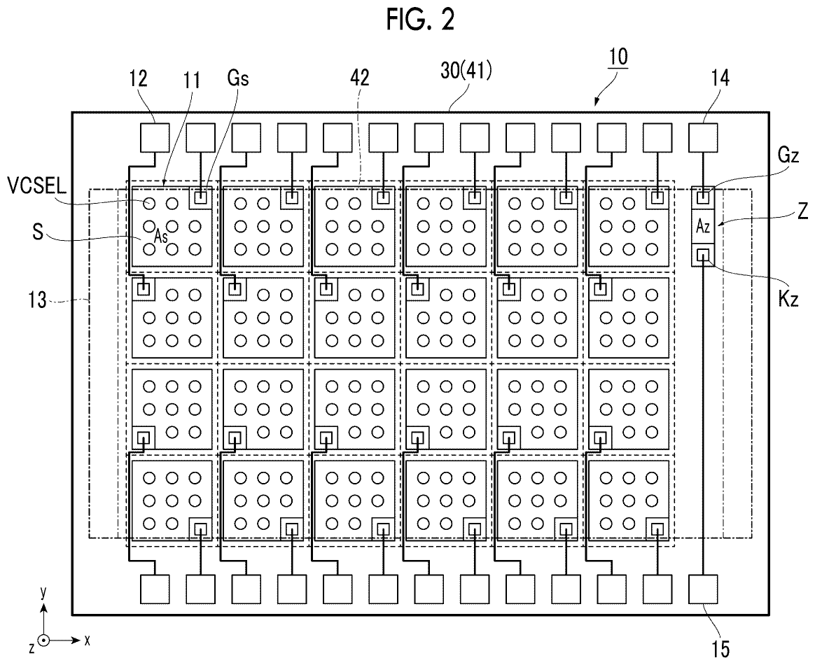

As will be described later, the light emitting device 10 includes a plurality of light emitting blocks 11. The light emitting block 11 includes a light emitting element. The light emitting element will be described as a vertical cavity surface emitting laser (VCSEL) below. The vertical cavity surface emitting laser is referred to as a VCSEL. Here, one light emitting point (or spot) is referred to as a VCSEL. The light emitting block 11 is configured to include at least one VCSEL (refer to FIG. 2 described below). In a case where the light emitting block 11 includes a plurality of light emitting points, the plurality of light emitting points may be collectively referred to as a multi-spot VCSEL. The vertical cavity surface emitting laser (VCSEL) is an example of a light emitting element and an example of a surface emitting laser.

In a case where the driver 50 transitions from an off state to an on state, the driver 50 supplies a current to turn on the VCSEL of the light emitting block 11. In a case where the driver 50 transitions from the on state to the off state, the driver 50 cuts off the current to turn off the VCSEL of the light emitting block 11. A period in which the driver 50 is turned on is a turn-on period.

The turn-on control unit 60 supplies a signal for controlling on/off of the driver 50 to the driver 50. The signal for controlling on/off of the driver 50 is referred to as a turn-on control signal below.

The discharge control unit 70 supplies a signal for controlling the discharge of charges accumulated in a case where the light emitting block 11 is turned on, to the light emitting device 10. The signal for controlling the discharge will be referred to as a discharge control signal below.

The adjustment unit 80 adjusts a timing of supplying a signal for starting the discharge in the discharge control signal in accordance with a timing of turning off the light emitting block 11 in the turn-on control signal and the number of the light emitting blocks 11 that are turned on.

The selection unit 90 selects the light emitting block 11 to be turned on from the plurality of light emitting blocks 11 and supplies a signal for setting the VCSEL of the light emitting block 11 in a state of being able to turn on, to the selected light emitting device 10. The signal for setting the VCSEL of the selected light emitting block 11 to be turned on in a state of being able to turn on is referred to as a selection signal below.

The control unit 8 controls the light emitting apparatus 1 and the 3D sensor 7. The control of the control unit 8 may include a function of measuring a distance to a measurement target object based on a time measured by the 3D sensor 7. The three-dimensional shape measuring unit 9 acquires the distance to the measurement target object from the control unit 8 and measures a three-dimensional shape of the measurement target object.

The control unit 8 is configured as, for example, a computer including a CPU, a ROM, a RAM, and the like. The ROM includes a non-volatile rewritable memory, for example, a flash memory. A program stored in the ROM is loaded onto the RAM, and the CPU executes the program to control the light emitting apparatus 1 and the 3D sensor 7.

In FIG. 1, the control unit 8 is provided outside the light emitting apparatus 1. Any or each of the turn-on control unit 60, the discharge control unit 70, the adjustment unit 80, or the selection unit 90 may be configured in the similar manner to the control unit 8. In addition, the control unit 8 may include any or all of the turn-on control unit 60, the discharge control unit 70, the adjustment unit 80, and the selection unit 90.

The three-dimensional shape measuring unit 9 is configured in the similar manner to the control unit 8, and measures the three-dimensional shape of a measurement target object from a distance to the measurement target object. The control unit 8 may have a function of the three-dimensional shape measuring unit 9.

### Planar Shape of Light Emitting Device 10

FIG. 2 is a diagram showing an example of a planar shape of the light emitting device 10 to which the first exemplary embodiment is applied. A horizontal direction of the paper surface is defined as an x direction, an upward direction of the paper surface is defined as a y direction, and a front surface direction of the paper surface is defined as a z direction. A planar shape is a shape on a surface side of a substrate 30 (shape on an x-y plane) which will be described later, and a cross-sectional shape which will be described later is a shape of a cross section perpendicular to the substrate 30.

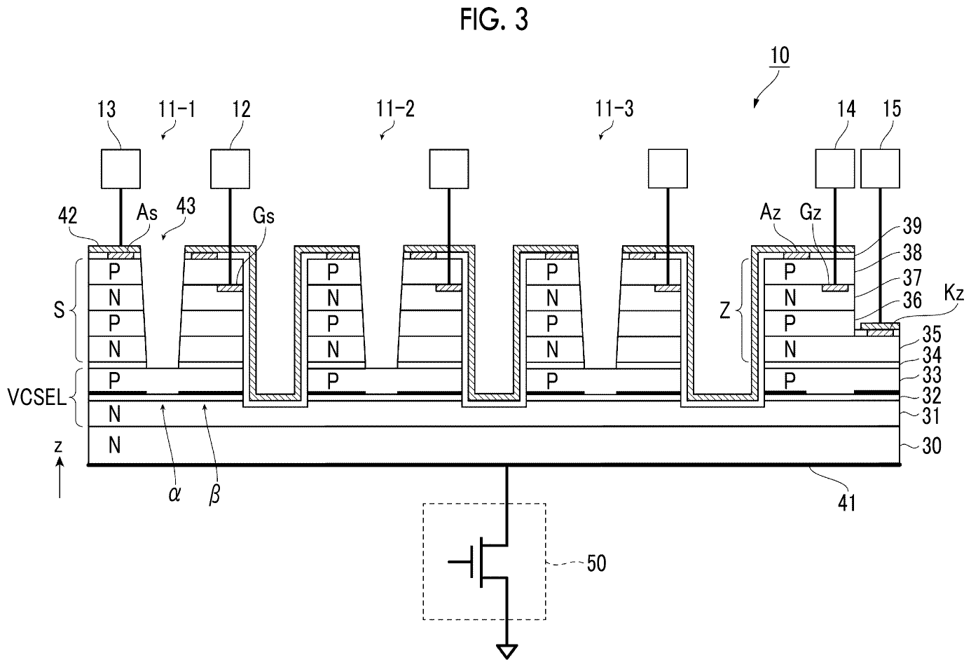

The light emitting device 10 is configured by a GaAs-based compound semiconductor as an example. As shown in the cross-sectional view (see FIG. 3 which will be described later), the light emitting device 10 is configured in a manner that a plurality of semiconductor layers are laminated on a substrate 30. The plurality of laminated semiconductor layers are referred to as a laminated semiconductor layer.

The light emitting device 10 includes a plurality of light emitting blocks 11 provided on a substrate 30, a discharge thyristor Z, a selection signal pad 12, an anode electrode 42, an anode pad 13, a discharge signal pad 14, and a cathode pad 15. The discharge thyristor Z is an example of a discharge element.

In FIG. 2, the light emitting device 10 includes 24 light emitting blocks 11 as an example. Six light emitting blocks 11 are arranged in the x direction and four light emitting blocks 11 are arranged in the y direction. The planar shape (shape in the x-y plane) of the light emitting block 11 is a square shape as an example. A semiconductor layer between the light emitting blocks 11 (a portion indicated by the broken line in FIG. 2) is removed by mesa etching, and thus the light emitting blocks 11 are electrically isolated. The reference numeral is given to the light emitting block 11 located at the upper left end of the paper surface, and the reference numerals will be omitted for the other light emitting blocks 11.

The light emitting block 11 is configured in a manner that a light emitting element (here, a VCSEL) and a setting thyristor S are laminated in this order on the substrate 30. The cathode of the VCSEL is located on the substrate 30 side, and the anode of the setting thyristor S is located on the side far from the substrate 30. A cathode electrode 41 is provided on the back surface of the substrate 30 (denoted by 30 (41) in FIG. 2). The cathode electrode 41 may be referred to as a back surface electrode. The setting thyristor S is an example of a setting element.

The light emitting block 11 includes eight VCSELs as an example. One setting thyristor S is provided on eight VCSELs. In the light emitting block 11, three positions in the x direction and three positions in the y direction, at which the VCSELs can be disposed, are provided at equal intervals. However, at one place, the VCSEL is not disposed, and a gate Gs of a setting thyristor S is provided. The gate Gs of the setting thyristor S is connected to the selection signal pad 12. The selection signal pad 12 is connected to the selection unit 90 shown in FIG. 1.

The discharge thyristor Z has the similar configuration to the setting thyristor S, and a gate Gz is connected to the discharge signal pad 14. The discharge signal pad 14 is connected to the discharge control unit 70 shown in FIG. 1. A cathode Kz of the discharge thyristor Z is connected to the cathode pad 15. The cathode pad 15 is connected to the cathode electrode 41 in which the cathode Kz of the discharge thyristor Z is provided on the back surface of the substrate 30.

An anode As of the setting thyristor S and an anode Az of the discharge thyristor Z are connected to the anode electrode 42. The anode electrode 42 is connected to the anode pad 13 provided continuously on the side of the substrate 30 where the light emitting block 11 is not provided in the ±x direction. In FIG. 2, the anode electrode 42 and the anode pad 13 are indicated by one-dot chain lines. In addition, the anode As of the setting thyristor S and the anode Az of the discharge thyristor Z are covered with one anode electrode 42. A DC voltage is supplied to the anode pad 13 from a power source VLD. The DC voltage supplied by the power source VLD is referred to as a power source voltage VLD. The cathode electrode 41 is connected to the driver 50 illustrated in FIG. 1.

The light emitting device 10 includes the 24 light emitting blocks 11, but may include a number of light emitting blocks 11 other than 24. The light emitting block 11 includes eight VCSELs, but may include a number of VCSELs other than eight. The light emitting block 11 only needs to include at least one VCSEL. The arrangement of the light emitting block 11 and the VCSELs may be an arrangement other than the arrangement shown in FIG. 2. The light emitting device 10 includes one discharge thyristor Z, but may include a plurality of discharge thyristors Z.

### Cross-Sectional Structure of Light Emitting Device 10

FIG. 3 is a cross-sectional view showing an example of a cross-sectional structure of the light emitting device 10 to which the first exemplary embodiment is applied. The upward direction of the paper surface is the z direction. FIG. 3 shows three light emitting blocks 11 (in FIG. 3, light emitting blocks 11-1 to 11-3) and the discharge thyristor Z. It is assumed that the light emitting block 11 includes one VCSEL. In a case where the light emitting block 11 includes a plurality of VCSELs, a plurality of light emission ports 43 may be provided in the light emitting block 11.

First, the light emitting block 11 will be described. The light emitting block 11 is configured by laminating the VCSEL and the setting thyristor S on the substrate 30 in this order.

The VCSEL is configured, for example, in a manner that an n-type cathode layer (n-cathode layer) 31, a light emitting layer 32, and a p-type anode layer (p-anode layer) 33 are laminated on a surface (the +z direction side) of an n-type GaAs substrate 30. The n-cathode layer 31 is, for example, a distributed Bragg reflector (DBR) in which AlGaAs layers having different Al compositions are alternately laminated. The light emitting layer 32 is, for example, an active area including a quantum well layer sandwiched between an upper spacer layer and a lower spacer layer. The p-anode layer 33 is an upper distributed Bragg reflector in which, for example, AlGaAs layers having different Al compositions are alternately laminated, similarly to the n-cathode layer 31. In the VCSEL, the n-cathode layer 31 functions as a cathode, the light emitting layer 32 functions as a light emitting layer, and the p-anode layer 33 functions as an anode. The n-cathode layer 31, the light emitting layer 32, and the p-anode layer 33 are laminated semiconductor layers constituting the VCSEL.

A tunnel junction layer 34 is laminated on the p-anode layer 33.

The setting thyristor S is configured by laminating an n-type cathode layer (n-cathode layer) 35, a p-type gate layer (p-gate layer) 36, an n-type gate layer (n-gate layer) 37, and a p-type anode layer (p-anode layer) 38 on a tunnel junction layer 34. For example, the n-cathode layer 35 and the n-gate layer 37 are n-type AlGaAs layers, and the p-gate layer 36 and the p-anode layer 38 are p-type AlGaAs layers. In the setting thyristor S, the n-cathode layer 35 functions as a cathode, the p-gate layer 36 functions as a p-gate, the n-gate layer 37 functions as an n-gate, and the p-anode layer 38 functions as an anode. Here, the thyristor is referred to as the setting thyristor S, but the setting thyristor S is a thyristor configured by four semiconductor layers. The n-cathode layer 35, the p-gate layer 36, the n-gate layer 37, and the p-anode layer 38 are laminated semiconductor layers constituting the setting thyristor S. The n-cathode layer 31, the light emitting layer 32, the p-anode layer 33, the tunnel junction layer 34, the n-cathode layer 35, the p-gate layer 36, the n-gate layer 37, and the p-anode layer 38 may also be referred to as laminated semiconductor layers.

The p-anode layer 38, the n-gate layer 37, the p-gate layer 36, the n-cathode layer 35, and the tunnel junction layer 34 of the setting thyristor S laminated on the upper side of the VCSEL are removed by etching to expose the p-anode layer 33, whereby a light emission port 43 that emits light from the VCSEL is configured. The setting thyristor S is configured by the n-cathode layer 35, the p-gate layer 36, the n-gate layer 37, and the p-anode layer 38 that surround the light emission port 43 of the VCSEL.

A p-type ohmic electrode (p-ohmic electrode) that is in ohmic contact with the p-anode layer 38 is provided on the p-anode layer 38. The p-ohmic electrode is an anode terminal of the setting thyristor S. The anode will be referred to as an anode As below. An n-type ohmic electrode (n-ohmic electrode) that is in ohmic contact with the n-gate layer 37 is provided on the n-gate layer 37 exposed by removing a portion of the p-anode layer 38 by etching. The n-ohmic electrode is a gate terminal of the setting thyristor S. The gate is referred to as a gate Gs below.

Between the light emitting blocks 11, the light emitting layer 32, the p-anode layer 33, the tunnel junction layer 34, the n-cathode layer 35, the p-gate layer 36, the n-gate layer 37, and the p-anode layer 38 are removed by etching (mesa etching) and are electrically isolated from each other.

An insulating layer 39 is provided on the isolated light emitting block 11. An anode electrode 42 that is connected to the p-ohmic electrode (the anode As of the setting thyristor S) on the p-anode layer 38 through a through-hole provided in the insulating layer 39 is provided. The anode electrode 42 is connected to the anode pad 13.

On the other hand, the n-ohmic electrode (the gate Gs of the setting thyristor S) on the n-gate layer 37 is connected to the selection signal pad 12 through the through-hole provided in the insulating layer 39. In FIG. 3, the gate Gs is referred to as being connected to the selection signal pad 12 through the p-anode layer 38, but the p-anode layer 38 at a portion where the gate Gs is provided is removed.

The cathode electrode 41 that is in ohmic contact with the substrate 30 is provided on the back surface (the −z direction side) of the substrate 30. The cathode electrode 41 is connected to the driver 50.

As described above, the VCSEL of the light emitting block 11 and the setting thyristor S are connected in series between the cathode electrode 41 and the anode electrode 42 on the VCSEL side. The plurality of light emitting blocks 11 are connected in parallel between the cathode electrode 41 and the anode electrode 42.

The tunnel junction layer 34 is provided between the p-anode layer 33 of the VCSEL and the n-cathode layer 35 of the setting thyristor S. In a case where a voltage in which the anode electrode 42 side is set to being positive (+) and the cathode electrode 41 is set to being negative (−) is applied, a reverse bias is generated between the n-cathode layer 35 of the setting thyristor S and the p-anode layer 33 of the VCSEL, and thus it is difficult for a current to flow. The tunnel junction layer 34 causes a current to easily flow even in a case where the n-cathode layer 35 of the setting thyristor S and the p-anode layer 33 of the VCSEL have a relationship of a reverse bias. The tunnel junction layer 34 is a junction of a p⁺⁺ layer such as GaAs and AlGaAs, in which p-type impurities on the p-anode layer 33 side of the VCSEL are doped with high concentration, and an n⁺⁺ layer such as GaAs and AlGaAs, in which n-type impurities on the n-cathode layer 35 side of the setting thyristor S are doped with high concentration. In the tunnel junction layer 34, since the width of a depletion area is narrow, even in a case where a relationship of a reverse bias is satisfied, electrons tunnel from the conduction band on the n⁺⁺ layer side to the valence band on the p⁺⁺ layer side. As a result, the current is likely to flow from the n-cathode layer 35 of the setting thyristor S to the p-anode layer 33 of the VCSEL. The VCSEL and the setting thyristor S are laminated through the tunnel junction layer 34 and are connected in series.

The p-anode layer 33 includes a current narrowing layer. The current narrowing layer is configured by an AlAs layer having a higher oxidation rate than AlGaAs and the like. A portion surrounding the light emission port 43 is oxidized to form a current blocking portion β, and a portion of the light emission port 43 is a non-oxidized current-carrying portion α. The current narrowing layer concentrates the current on a central portion of the VCSEL having a resonator structure.

Next, the discharge thyristor Z will be described. The discharge thyristor Z is configured by laminating the n-cathode layer 35, the p-gate layer 36, the n-gate layer 37, and the p-anode layer 38. In the discharge thyristor Z, the n-cathode layer 35 functions as a cathode, the p-gate layer 36 functions as a p-gate, the n-gate layer 37 functions as an n-gate, and the p-anode layer 38 functions as an anode. Here, the thyristor is referred to as the discharge thyristor Z, and the discharge thyristor S is a thyristor configured by four semiconductor layers. The n-cathode layer 35, the p-gate layer 36, the n-gate layer 37, and the p-anode layer 38 are laminated semiconductor layers constituting the discharge thyristor Z. The laminated semiconductor layer constituting the discharge thyristor Z is the same as the laminated semiconductor layer constituting the setting thyristor S. As a result, the light emitting device 10 is easily manufactured. Under the discharge thyristor Z, there are the n-cathode layer 31, the light emitting layer 32, the p-anode layer 33, and the tunnel junction layer 34 that constitute the VCSEL in the light emitting block 11.

A p-type ohmic electrode (p-ohmic electrode) that is in ohmic contact with the p-anode layer 38 is provided on the p-anode layer 38. The p-ohmic electrode is an anode terminal of the discharge thyristor Z. The anode will be referred to as an anode Az below. An n-type ohmic electrode (n-ohmic electrode) that is in ohmic contact with the n-gate layer 37 is provided on the n-gate layer 37 exposed by removing a portion of the p-anode layer 38 by etching. The n-ohmic electrode is a gate terminal of the discharge thyristor Z. The gate is referred to as a gate Gz below. Further, an n-ohmic electrode is provided on the n-cathode layer 35 exposed by removing a portion of the p-anode layer 38, the n-gate layer 37, and the p-gate layer 36 by etching. The n-ohmic electrode is a cathode electrode of the discharge thyristor Z. This cathode electrode is referred to as a cathode Kz below.

In the discharge thyristor Z and the light emitting block 11, the light emitting layer 32, the p-anode layer 33, the tunnel junction layer 34, the n-cathode layer 35, the p-gate layer 36, the n-gate layer 37, and the p-anode layer 38 are removed by etching and are electrically isolated from each other, as in the case of the light emitting blocks 11.

The p-ohmic electrode (anode Az of the discharge thyristor Z) on the p-anode layer 38 is connected to the anode electrode 42 through the through-hole provided in the insulating layer 39.

The n-ohmic electrode (cathode Kz of the discharge thyristor Z) provided in the n-cathode layer 35 is connected to the cathode pad 15. The cathode pad 15 is connected to the cathode electrode 41. The discharge thyristor Z is connected in parallel to the light emitting block 11 between the cathode electrode 41 and the anode electrode 42.

In FIG. 3, an n-ohmic electrode is provided in the n-cathode layer 35 and used as the cathode Kz of the discharge thyristor Z. In the discharge thyristor Z, the p-anode layer 33 may be exposed, and a p-ohmic electrode may be provided on the p-anode layer 33 to be used as the cathode Kz of the discharge thyristor Z. Since the p-anode layer 33 is connected to the n-cathode layer 35 through the tunnel junction layer 34, the p-anode layer 33 and the n-cathode layer 35 have the same potential. In this manner, an etching step of providing the cathode Kz of the discharge thyristor Z is the same as a step of providing the light emission port 43 of the light emitting block 11, and a step of exposing the n-cathode layer 35 is not necessary.

### Equivalent Circuit of Light Emitting Device 10

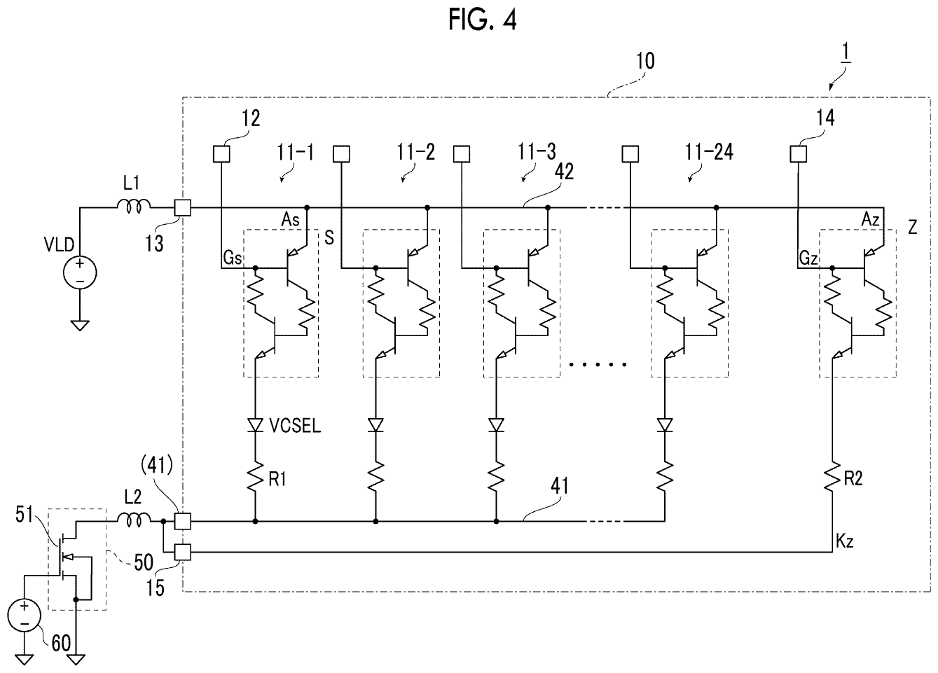

FIG. 4 shows an equivalent circuit of the light emitting device 10 to which the first exemplary embodiment is applied. In FIG. 4, the light emitting device 10 shows 24 light emitting blocks 11 (in FIG. 4, light emitting blocks 11-1 to 11-24) and the discharge thyristor Z. In FIG. 4, in addition to the light emitting device 10, the power source VLD and the driver 50 are collectively shown.

In FIG. 4, the setting thyristor S and the discharge thyristor Z are shown by a combination of a pnp transistor and an npn transistor.

The light emitting block 11 is configured in a manner that the setting thyristor S and the VCSEL are connected in series. The cathode (emitter of the npn transistor) of the setting thyristor S and the anode of the VCSEL are connected to each other. The anode As (emitter of the pnp transistor) of the setting thyristor S is connected to the anode electrode 42, and the cathode of the VCSEL is connected to the cathode electrode 41 through a resistance R1. The resistance R1 is an equivalent resistance that equivalently represents the internal resistance in the setting thyristor S and the VCSEL.

The plurality of light emitting blocks 11 are connected in parallel between the anode electrode 42 and the cathode electrode 41.

In the discharge thyristor Z, an anode Az (emitter of the pnp transistor) is connected to the anode electrode 42, and a cathode Kz is connected to the cathode pad 15 through a resistance R2. The cathode pad 15 is connected to the cathode electrode 41 outside the light emitting device 10.

The anode pad 13 is connected to the power source VLD through a parasitic inductance L1. The cathode electrode 41 is connected to the driver 50 through a parasitic inductance L2. The parasitic inductance L1 is an inductance that is parasitic on a wiring line connecting the light emitting device 10 and the power source VLD in a case where the light emitting device 10 is mounted on the light emitting apparatus 1. The parasitic inductance L2 is an inductance that is parasitic on a wiring line connecting the light emitting device 10 and the driver 50. In addition to the inductance, resistance and capacitance are generated in the wiring lines for connections, but the influence of the inductance is the greatest. In FIG. 4, the inductance having a large influence is referred to as parasitic inductances L1 and L2.

The driver 50 is, for example, an n-channel MOS transistor (nMOS transistor) 51 and drives the light emitting block 11 with a constant current. In the nMOS transistor 51 of the driver 50, the source is grounded and the drain is connected to the cathode electrode 41. The light emitting device 10 is so-called low-side driven.

Here, the turning on and the turning off of the VCSEL in the light emitting block 11 will be described. The turning on and the turning off of the VCSEL in the light emitting block 11 will be referred to as the turning on and the turning off of the light emitting block 11. A voltage of each signal is shown in parentheses as an example. In addition, the forward voltage of the pn junction is set to 1.5 V. In the pn junction, in a case where a voltage of 1.5 V or more is applied, the pn junction is in a forward bias, and thus a current easily flows, and in a case where a voltage of less than 1.5 V is applied, the pn junction is in a reverse bias, and thus a current hardly flows. In a state where a voltage is applied between an anode (emitter of pnp transistor) and a cathode (emitter of npn transistor) in a thyristor and a bias is applied in a forward direction between an anode (emitter of pnp transistor) and a gate (base of pnp transistor), the pnp transistor is turned on. As a result, the npn transistor is turned on. As a result, the thyristor is turned on. The transition of the thyristor from an off state to an on state is referred to as turn-on.

A state in which none of the light emitting blocks 11 are turned on and a state before selecting the light emitting block 11 to be turned on are referred to as an initial state. In the initial state, the power source voltage VLD (9 V) is applied to the anode pad 13 of the light emitting device 10 from the power source VLD. As a result, the power source voltage VLD (9 V) is applied to the cathode electrode 41. A selection signal (9 V) for not selecting any light emitting block 11 is supplied to all the selection signal pads 12 from the selection unit 90. The selection signal (9 V) is the same as the power source voltage VLD (9 V) applied to the anode As of the setting thyristor S. The emitter (anode As of the setting thyristor S) and the base (gate Gs of the setting thyristor S) of a pnp transistor of the setting thyristor S are at the same potential (power source voltage VLD (9 V)). In other words, the emitter (anode As of the setting thyristor S) and the base (gate Gs of the setting thyristor S) of the pnp transistor of the setting thyristor S are not in a forward bias.

The driver 50 is supplied with a turn-on control signal (0 V) for turning off the nMOS transistor 51 of the driver 50 from the turn-on control unit 60. Since the nMOS transistor 51 of the driver 50 is off, the cathode electrode 41 of the light emitting device 10 is set to the power source voltage VLD (9 V). The cathode (emitter of an npn transistor) of the setting thyristor S and the anode of the VCSEL are set to a power source voltage VLD (9 V). The anode (emitter of the pnp transistor) and the cathode (emitter of the npn transistor) of the setting thyristor S are at the same potential (power source voltage VLD (9 V)).

A case where one light emitting block 11, here, the light emitting block 11-1 is turned on will be described. The selection unit 90 supplies a selection signal (7 V) for selecting the light emitting block 11-1 to the selection signal pad 12 of the light emitting block 11-1. Then, the voltage of the gate Gs of the setting thyristor S of the light emitting block 11-1 is 7 V, and the emitter (anode As of the setting thyristor S) and the base (gate Gs of the setting thyristor S) of the pnp transistor is forward biased. As a result, the setting thyristor S is set to a state in which turn-on is possible (turn-on enable state). Since the anode (emitter of the pnp transistor) and the cathode (emitter of the npn transistor) of the setting thyristor S are at the same potential (power source voltage VLD (9 V)), the setting thyristor S is not turned on. Such a state will be referred to as a turn-on enable state. In a case where the setting thyristor S is turned on, a current flows to the VCSEL to emit light. In a case where the setting thyristor S is in a turn-on enable state e, the VCSEL is in a light emitting state. Therefore, the setting thyristor S is referred to as an element that sets the setting thyristor S to a state where the VCSEL can emit light. The selection signal (7 V) is a value set in consideration of the forward voltage (1.5 V) of the pn junction with respect to 9 V of the power source voltage VLD.

Here, in a case where the turning-on signal (1.2 V) for turning on the nMOS transistor 51 is supplied from the turn-on control unit 60 to the driver 50, the nMOS transistor 51 is transitioned from the off state to the on state. Then, the voltage (cathode voltage) of the cathode electrode 41 is drawn to the ground voltage (0 V) side. Then, the setting thyristor S in the turn-on enable state in the light emitting block 11-1 is turned on. Then, a current flows to the VCSEL through the setting thyristor S, and the VCSEL emits light. That is, the light emitting block 11-1 is turned on. In a case where the light emitting block 11-1 is turned on, the nMOS transistor 51 of the driver 50 is operated as a constant current source. In this case, the voltage of the drain (cathode electrode 41) of the nMOS transistor 51 is set to about 1 V. The turning-on signal (1.2 V) is a voltage that is higher than the threshold voltage of the nMOS transistor 51 of the driver 50 and that turns on the nMOS transistor 51.

Next, a case where the light emitting block 11-1 that is being turned on is turned off will be described.

The turn-on control signal (0 V) for turning off the nMOS transistor 51 of the driver 50 is supplied from the turn-on control unit 60. In a case where the nMOS transistor 51 is switched from the on state to the off state, the current flowing to the VCSEL is blocked through the setting thyristor S, and the light emission of the VCSEL is stopped. That is, the light emitting block 11-1 is turned off. In a case where the selection signal (7V) is supplied to the gate Gs of the setting thyristor S of the light emitting block 11-1, the setting thyristor S maintains a turn-on enable state. In a case where the turn-on control signal (1.2 V) for turning on the nMOS transistor 51 of the driver 50 is supplied from the turn-on control unit 60, the setting thyristor S of the light emitting block 11-1 is turned on, and the VCSEL emits light. That is, the light emitting block 11-1 is turned on again. However, in a case where the transition is made to the selection signal (9 V) indicating that the selection signal (7 V) is not selected during the turn-on of the light emitting block 11-1, even in a case where the light emitting block 11-1 is turned off and the turn-on control signal (1.2 V) for turning on the nMOS transistor 51 of the driver 50 is supplied from the turn-on control unit 60, the setting thyristor S of the light emitting block 11-1 does not turn on, and the light emitting block 11-1 is not turned on again.

The setting thyristor S in the on state does not transition to the off state even in a case where the selection signal supplied to the gate Gs is transitioned from the selection signal (7 V) selected by the selection signal (7 V) to the non-selected selection signal (9 V). In a case where the current is not flowing, the setting thyristor S transitions to the off state. Therefore, the selection signal (7 V) to be selected may be changed to the non-selection signal (9 V) not to be selected, for example, in a case where the nMOS transistor 51 of the driver 50 is switched from on to off and the current flows to the setting thyristor S, or after the current does not flow.

Next, a case where the light emitting block 11-1 is maintained in a state where the light emitting block 11-1 is turned off (turn-off state) will be described. The selection unit 90 may maintain the supply of the selection signal (9 V) not to select the light emitting block 11-1. In a case where the selection signal (9 V) is supplied to the light emitting block 11-1, the setting thyristor S does not enter the turn-on enable state as described above. A turning-on signal (1.2 V) for turning on the nMOS transistor 51 of the driver 50 is supplied from the turn-on control unit 60 to the nMOS transistor 51 of the driver 50, and even in a case where the nMOS transistor 51 of the driver 50 is switched from off to on, the setting thyristor S of the light emitting block 11-1 is not turned on, and a current does not flow to the VCSEL. That is, the light emitting block 11-1 maintains the turn-off state.

As described above, in the plurality of light emitting blocks 11, by supplying the selection signal (7 V) to the light emitting block 11, the light emitting block 11 to be turned on is selected. The number of light emitting blocks 11 to be simultaneously turned on may be one, a plurality, or all.

Light Emitting Device 10A that does not Include Discharge Thyristor Z

Here, before the discharge thyristor Z in the light emitting device 10 to which the first exemplary embodiment is applied is described, a problem in a case where the block irradiation is performed using the light emitting device 10A not comprising the discharge thyristors Z will be described.

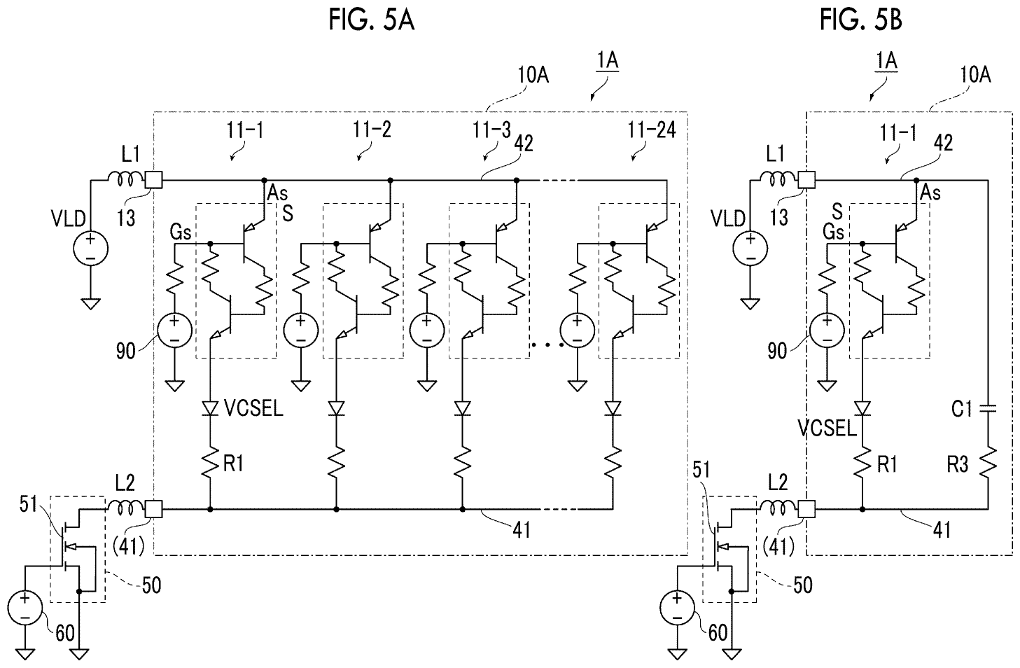

FIGS. 5A and 5B show an equivalent circuit for describing a light emitting apparatus 1A using a light emitting device 10A that does not include the discharge thyristor Z and to which the first exemplary embodiment is not applied. FIG. 5A shows an equivalent circuit showing 24 light emitting blocks 11, and FIG. 5B shows an equivalent circuit in a case where one light emitting block 11 is turned on and other light emitting blocks 11 are set in a turned-off state.

FIG. 5A shows a configuration in which the discharge thyristor Z is removed in FIG. 4. In addition, instead of the selection signal pad 12, the selection unit 90 that supplies a selection signal is shown. The others are similar to FIG. 4, and thus, the description thereof will be omitted using the same reference numerals.

In FIG. 5B, one light emitting block 11 (in FIG. 5B, the light emitting block 11-1) is turned on, and the other light emitting blocks 11 (the light emitting blocks 11-2 to 11-24 in FIG. 5A) are turned off.

As shown in FIG. 5A, the light emitting blocks 11 are connected in parallel between the anode electrodes 42 and the cathode electrodes 41. The light emitting block 11 is connected in series with the setting thyristor S and the VCSEL. In a case where the light emitting block 11-1 is turned on, a current flows from the anode electrode 42 to the cathode electrode 41 through the light emitting block 11-1, and the VCSEL emits light. In this case, a current does not flow in the other light emitting blocks 11-2 to 11-24. However, since the other light emitting blocks 11-2 to 11-24 are provided between the anode electrode 42 and the cathode electrode 41, the capacitance, that is, the parasitic capacitance is obtained. This capacitance is connected in parallel to the light emitting block 11-1. Therefore, in FIG. 5B, the other light emitting blocks 11-2 to 11-24 are referred to as a parallel capacitance C1. A resistance R3 is an equivalent resistance that equivalently represents the internal resistance in the other light emitting blocks 11-2 to 11-24.

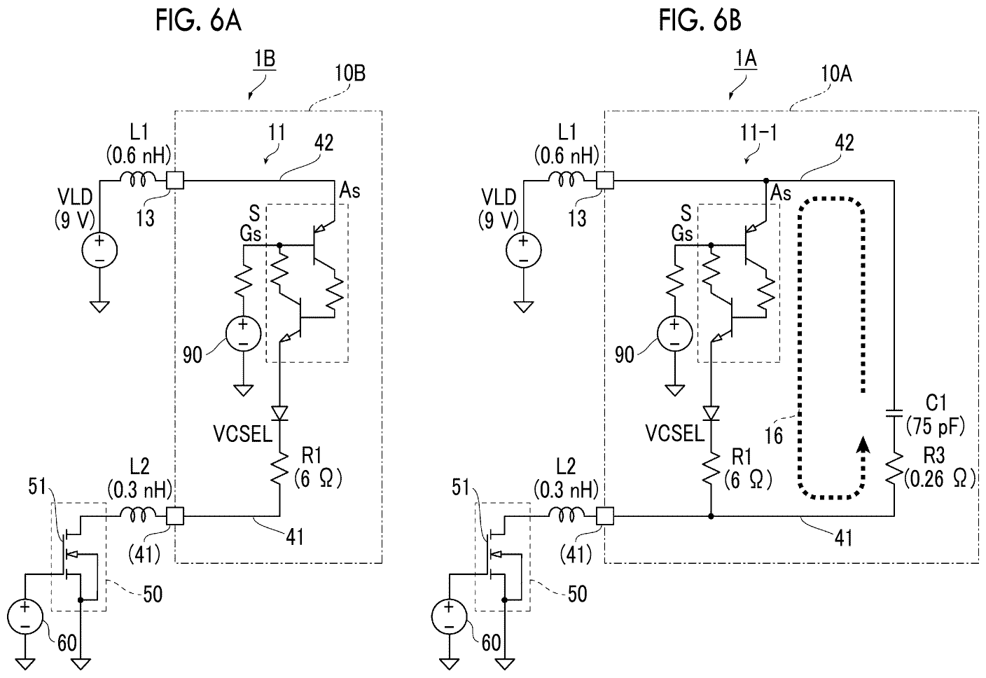

FIGS. 6A and 6B show an equivalent circuit for describing an influence of the parallel capacitance C1. FIG. 6A shows a light emitting apparatus 1B using a light emitting device 10B including one light emitting block 11, and FIG. 6B shows a light emitting apparatus 1A using a light emitting device 10A including 24 light emitting blocks 11. In the light emitting apparatus 1B of FIG. 6A, one light emitting block 11 is provided. In FIG. 6A, the parallel capacitance C1 illustrated in FIG. 5B is not provided. In the light emitting apparatus 1A of FIG. 6B, one light emitting block 11 is turned on, and the other 23 light emitting blocks 11 are turned off. FIG. 6B is the same as FIG. 5B.

The current flowing in the VCSEL is obtained by simulation. The light emission state of the VCSEL can be determined by the current flowing in the VCSEL. In the simulation, as shown in FIGS. 6A and 6B, the power source voltage VLD is set to 9 V, the parasitic inductance L1 is set to 0.6 nH, the parasitic inductance L2 is set to 0.3 nH, and the resistance R1 is set to 6Ω. Further, as shown in FIG. 6B, the parallel capacitance C1 is 75 pF, and the resistance R3 is 0.26Ω.

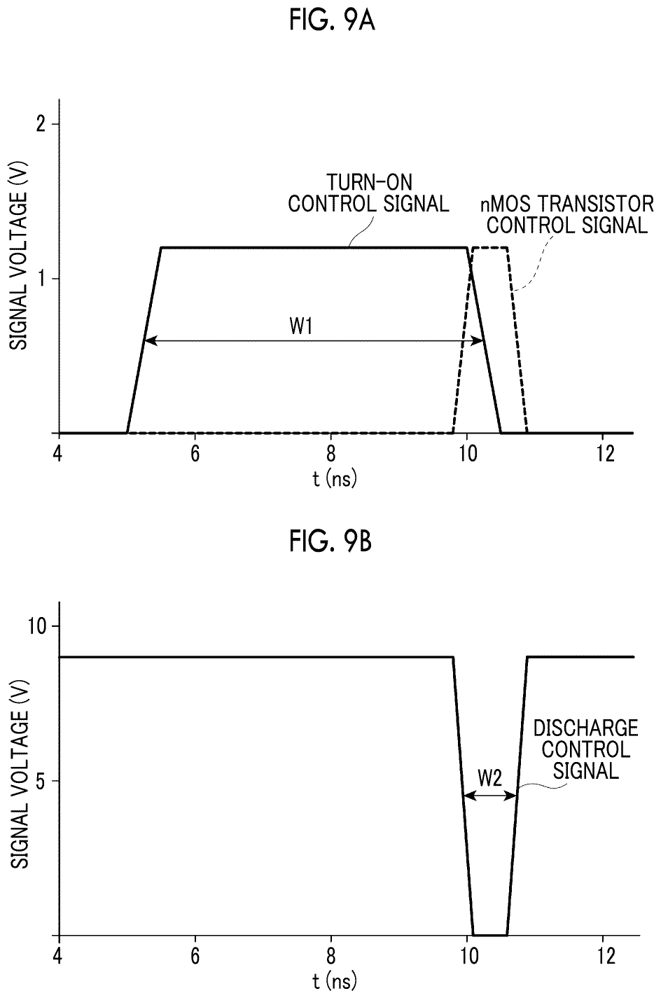

The turn-on control signal supplied from the turn-on control unit 60 to the driver 50 is the same as the turn-on control signal shown in FIG. 9A described below, and the amplitude is 1.2 V, the pulse width W1 is 5 ns, and the rising time and the falling time are 0.5 ns.

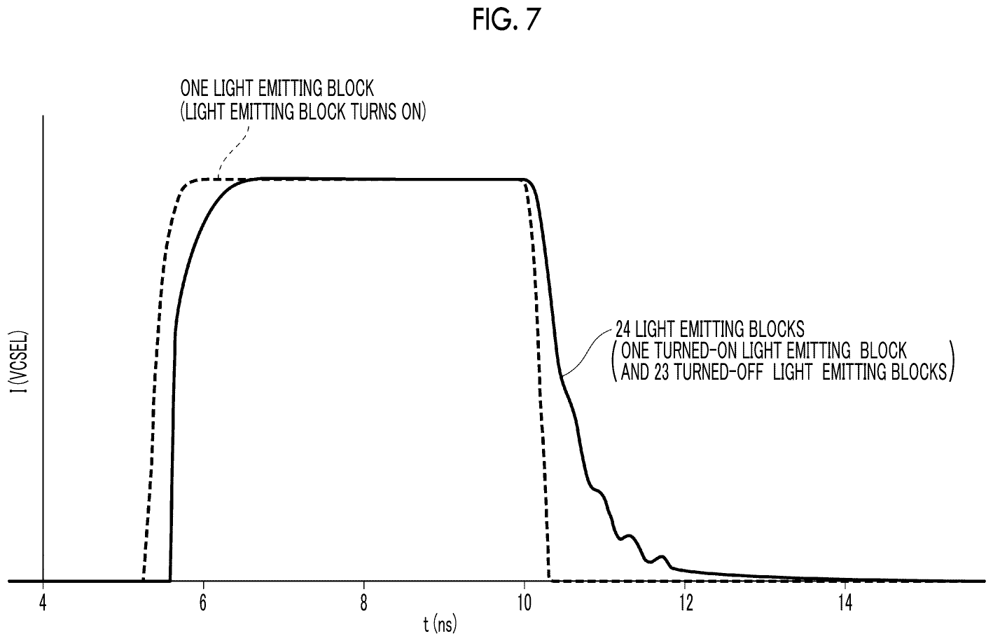

FIG. 7 is a result of simulating a current I flowing to the VCSEL by the equivalent circuit for describing the influence of the parallel capacitance C1. The horizontal axis represents a time t (ns), and the vertical axis represents a current I (VCSEL) flowing through the VCSEL. In the light emitting apparatus 1B (denoted as “one light emitting block” in FIG. 7) using the light emitting device 10B including one light emitting block 11 shown in FIG. 6A, the rising time and the falling time of the current I (VCSEL) flowing to the VCSEL are short. The falling time is about 50 ns. On the other hand, in the light emitting apparatus 1A (denoted as “24 light emitting blocks” in FIG. 7) using the light emitting device 10A including 24 light emitting blocks 11, the rising of the current I (VCSEL) flowing in the VCSEL is delayed and the falling time is longer than that in the light emitting apparatus 1B (“one light emitting block”). Since the falling time is long, the light emission of the VCSEL continues for a long time. In other words, the light emission of the VCSEL is long-lasting.

The reason why the light emitting apparatus 1A (“24 light emitting blocks”) is slower to start than the light emitting apparatus 1B (“one light emitting block”) is that the current that flows after the nMOS transistor 51 of the driver 50 is turned on first charges the parallel capacitance C1 and then flows to the VCSEL. The reason why the current I(VCSEL) flowing into the VCSEL rapidly rises is that, while the parallel capacitance C1 is being charged, the influence of the response of the parasitic inductances L1 and L2 of the current path, particularly, the voltage drop on the cathode electrode 41 side from 9 V to 1 V is mitigated.

The reason why the light emitting apparatus 1A (“24 light emitting blocks”) has a longer falling time than the light emitting apparatus 1B (“one light emitting block”) is that the charge accumulated in the parallel capacitance C1 is discharged through the VCSEL by the time constant of the resistance R1, the resistance R2, and the parallel capacitance C1. The charges accumulated in the parallel capacitance C1 are discharged through a path 16 shown by a broken line in FIG. 6B. The light emitting block 11-1 including the turned-on VCSEL is provided in the path 16. Therefore, the light emission of the VCSEL is prolonged. In the light emitting apparatus 1B (“one light emitting block”), since the parasitic capacitance that requires discharge is small, the current flowing to the VCSEL rapidly decreases.

As described above, in the block irradiation, all the light emitting blocks 11 that are not turned on are the parallel capacitance C1. The parallel capacitance C1 is in a range of several pF to 100 pF or more. Such a parallel capacitance C1 is a falling time of ns, and impairs the falling characteristic of the light emitting apparatus 1.

### Light Emitting Apparatus 1 Using Light Emitting Device 10 Including Discharge Thyristor Z

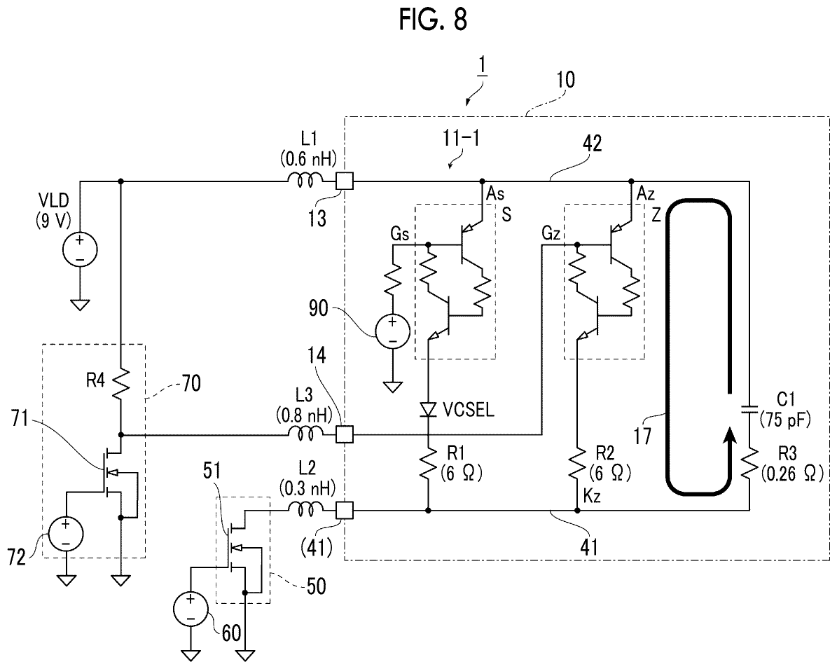

FIG. 8 shows an equivalent circuit of the light emitting apparatus 1 using the light emitting device 10 including the discharge thyristor Z, to which the first exemplary embodiment is applied. FIG. 8 shows the light emitting device 10, the driver 50, the turn-on control unit 60, and the discharge control unit 70 as the light emitting apparatus 1.

It is assumed that the light emitting device 10 includes 24 light emitting blocks 11. Then, one light emitting block 11 (in FIG. 8, the light emitting block 11-1) is selected and turned on, and the other light emitting blocks 11 (the light emitting blocks 11-2 to 11-24) are turned off. As described above, the light emitting block 11-1 is represented by a series connection of the setting thyristor S, the VCSEL, and the resistance R1. The light emitting block 11 that is turned off is represented by being connected in series to the parallel capacitance C1 and the resistance R3. The discharge thyristor Z and the resistance R2 that equivalently represents the internal resistance of the discharge thyristor Z are connected in series.

The series connection of the setting thyristor S, the VCSEL, and the resistance R1, the series connection of the parallel capacitance C1 and the resistance R3, and the series connection of the discharge thyristor Z and the resistance R2 are connected in parallel between the cathode electrode 41 and the anode electrode 42. Since the resistances R1, R2, and R3 are parasitic resistances, the light emitting block 11 in which the setting thyristor S and the VCSEL are connected in series and the discharge thyristor Z are connected in parallel.

The power source voltage VLD is supplied to the anode electrode 42 through the parasitic inductance L1. A drain of the nMOS transistor 51 of the driver 50 is connected to the cathode electrode 41 through the parasitic inductance L2. The source of the nMOS transistor 51 of the driver 50 is grounded. A turn-on control signal from the turn-on control unit 60 is supplied to a gate of the nMOS transistor 51 of the driver 50. On/off of the nMOS transistor 51 of the driver 50 is controlled by a turn-on control signal.

The discharge control unit 70 includes an nMOS transistor 71, a resistor R4, and an nMOS transistor control circuit 72. The nMOS transistor control circuit 72 supplies a signal (nMOS transistor control signal) for controlling turning on/off of the nMOS transistor 71. One terminal of the drain of the nMOS transistor 71 and the resistor R4 are connected to each other. The other terminal of the resistor R4 not connected to the nMOS transistor 71 is connected to the power source VLD. The source of the nMOS transistor 71 is grounded. An nMOS transistor control circuit 72 is connected to the gate of the nMOS transistor 71. The nMOS transistor control circuit 72 supplies an nMOS transistor control signal for turning on/off the nMOS transistor 71.

The gate Gz of the discharge thyristor Z is connected to a connection point between the drain of the nMOS transistor 71 of the discharge control unit 70 and the resistor R4 through the parasitic inductance L3. The parasitic inductance L3 is an inductance that is parasitic on a wiring line connecting the discharge signal pad 14 to which the gate Gz of the discharge thyristor Z is connected and the discharge control unit 70. A voltage at a connection point between the drain of the nMOS transistor 71 of the discharge control unit 70 and the resistor R4 is the discharge control signal, and is supplied to the gate Gz of the discharge thyristor Z.

The discharge thyristor Z operates in the same manner as the setting thyristor S described above. In a state where a voltage is applied between the anode Az and the cathode Kz of the discharge thyristor Z, in a case where the emitter (anode Az)-base (gate Gz) of the pnp transistor of the discharge thyristor Z is forward biased, the off-state discharge thyristor Z is turned on and transitions to the on state. In a case where the power source voltage VLD is 9 V, the emitter (anode Az) of the pnp transistor of the discharge thyristor Z is 9 V. In a case where the base (gate Gz) of the pnp transistor is 7.5 V (9 V−1.5 V) or less, the emitter (anode Az) and the base (gate Gz) of the pnp transistor is forward biased, and the discharge thyristor Z is turned on. On the contrary, in a case where the base (the gate Gz) of the pnp transistor is more than 7.5 V, the discharge thyristor Z is not turned on because the emitter (the anode Az) of the pnp transistor is not forward biased with respect to the base (the gate Gz).

In a state where a voltage is applied between the anode Az and the cathode Kz of the discharge thyristor Z, in a case where the nMOS transistor 71 of the discharge control unit 70 is off, a connection point between the drain of the nMOS transistor 71 and the resistor R4 is the power source voltage VLD (9 V). In this case, the discharge control signal is 9 V. In a case where the discharge control signal is 9 V, the gate Gz of the discharge thyristor Z is 9 V, and the discharge thyristor Z is maintained in an off state without being turned on. On the other hand, in a case where the nMOS transistor 71 of the discharge control unit 70 is turned on, a connection point between the drain of the nMOS transistor 71 and the resistor R4 is drawn to the ground potential (0 V) side. In this case, the discharge control signal changes toward 0 V. In a case where the discharge control signal is decreased to a voltage at which the discharge thyristor Z is turned on, the discharge thyristor Z is turned on. The discharge control signal turns on the discharge thyristor Z even in a case where the discharge control signal is not 0 V. The thyristor has a fast switching from the off state to the on state.

In the light emitting apparatus 1, in a case where the light emitting block 11 (in FIG. 8, the light emitting block 11-1) of the light emitting device 10 is turned off, the discharge thyristor Z is turned on. In a period in which the light emitting block 11-1 is turned on, the voltage applied to the cathode electrode 41 is 1 V, and the voltage applied to the anode electrode 42 is the power source voltage VLD (9 V). In a case where the light emitting block 11-1 is turned off and the discharge thyristor Z is turned on, the charges accumulated in the parallel capacitance C1 during the period in which the light emitting block 11-1 is turned on are discharged through the discharge path 17 through the discharge thyristor Z. Then, the cathode electrode 41 rises toward the power source voltage VLD (9 V). In a case where the power source voltage of the cathode electrode 41 is the power source voltage VLD (9 V), the anode Az and the cation Kz of the discharge thyristor Z have the same power source voltage VLD (9 V), and the discharge thyristor Z is turned off. In the light emitting device 10, the discharge path 17 is configured by a discharge thyristor Z. The discharge is also performed through the light emitting block 11-1 that is turned on, but here, a discharge path through the discharge thyristor Z is referred to as a discharge path 17.

A power source voltage VLD (9 V) is applied to the nMOS transistor 71 of the discharge control unit 70 through a resistor R4. Even in a case where the nMOS transistor 71 is turned on, the current flowing through the nMOS transistor 71 is limited by the resistor R4, so that the large current flowing through the nMOS transistor 71 is suppressed. In addition, the nMOS transistor 71 may supply a current for turning on the discharge thyristor Z, and the current capacity may be small. By providing the resistor R4, the discharge control unit 70 (drain of nMOS transistor 71) can be connected to the power source VLD, and it is not necessary to separately provide a power source for the discharge control unit 70 (drain of nMOS transistor 71).

The following values are used for the simulation of the current I flowing in the VCSEL shown next. The parasitic inductances L1 and L2, the parallel capacitance C1, and the resistances R1 and R3 are the same as the values described above, which are 0.6 nH, 0.3 nH, 75 pF, 6Ω, and 0.26Ω. The parasitic inductance L3 is 0.8 nH, and the resistance R2 is 6Ω.

FIGS. 9A and 9B are timing charts for describing the turn-on control signal and the discharge control signal used in the simulation. FIG. 9A shows a turn-on control signal, and FIG. 9B shows a discharge control signal. The turn-on control signal is a signal supplied from the turn-on control unit 60 to the driver 50. The discharge control signal is a signal supplied from the discharge control unit 70 (a connection point between the drain of the nMOS transistor 71 and the resistor R4) to the gate Gz of the discharge thyristor Z. In addition, in FIG. 9A, nMOS transistor control signals supplied to the gate of the nMOS transistor 71 by the nMOS transistor control circuit 72 in the discharge control unit 70 are collectively shown. In FIGS. 9A and 9B, the horizontal axis is the time t (ns), and the vertical axis is the signal voltage (V).

As shown in FIG. 9A, the turn-on control signal rises from 0 V to 1.2 V in 0.5 ns at a timing of 5 ns, and falls from 1.2 V to 0 V in 0.5 ns at a timing of 9.5 ns. The amplitude is 1.2 V. The turn-on control signal is a pulse signal having a cycle of 40 ns. The pulse width W1 (which may be referred to as a width) at the amplitude of 1/2 is 5 ns. The rising time and the falling time are 0.5 ns.

The nMOS transistor control signal rises from 0 V to 1.2 V in 0.3 ns at a timing of 9.8 ns, and falls from 1.2 V to 0 V in 0.3 ns at a timing of 10.3 ns. The amplitude is 1.2 V. The nMOS transistor control signal is a pulse signal having a cycle of 40 ns. The pulse width (which may be referred to as a width) at an amplitude of 1/2 is 0.8 ns.

As shown in FIG. 9B, the discharge control signal controlled by the nMOS transistor control signal falls from 9 V to 0 V in 0.3 ns at a timing of 9.8 ns, and rises from 0 V to 9 V in 0.3 ns at a timing of 10.3 ns. The amplitude is 9 V. The discharge control signal is a pulse signal having a cycle of 40 ns. The pulse width W2 (which may be referred to as a width) at the amplitude of 1/2 is 0.8 ns.

The discharge control signal starts to fall at a timing (10 ns) before 0.2 ns of a timing at which the turn-on control signal starts to fall. As described above, the discharge thyristor Z is turned on in a case where the gate Gz is 7.5 V or less. That is, the discharge thyristor Z is turned on in a period in which the turn-on control signal is 1.2 V, that is, the nMOS transistor 51 of the driver 50 is turned on.

As shown in FIGS. 9A and 9B, the timing at which the discharge control signal starts to fall may be before the turn-on control signal starts to fall or may be after the turn-on control signal falls. The fact that the discharge control signal falls at a time when the turn-on control signal falls means that a timing at which the discharge control signal starts to fall includes a time before the turn-on control signal starts to fall and a time after the turn-on control signal has fallen. In a case where the discharge control signal starts to fall before the turn-on control signal starts to fall, a current flows to the driver 50 from the power source VLD through the discharge thyristor Z (refer to FIG. 8), so that the power consumption increases. In order to reduce the power consumption, for example, it is preferable that the overlap between the turn-on control signal and the discharge control signal on the time axis is small.

In the above description, it is assumed that, in the turn-on control signal, the signal voltage at which the nMOS transistor 51 of the driver 50 is turned on is higher than the signal voltage at which the nMOS transistor 51 is turned off, and, in the discharge control signal, the signal voltage at which the discharge thyristor Z is turned on is lower than the signal voltage at which the discharge thyristor Z is maintained to be turned off. The turn-on control unit 60 and the discharge control unit 70 have different signal voltages depending on the configurations thereof. Therefore, it can be noted that the discharge control signal starts to change to the signal voltage for turning on the discharge thyristor Z in a case where the turn-on control signal changes to the signal voltage for turning off the driver 50 (nMOS transistor 51). The time when the turn-on control signal is changed to the signal voltage for turning off the driver 50 (nMOS transistor 51) may be immediately before or immediately after the driver 50 (nMOS transistor 51) is turned off.

Once the thyristor is turned on, the thyristor does not transition to the off state even in a case where the gate voltage is changed. From this, it is sufficient that the discharge control signal is a period (pulse width) in which the turn-on of the discharge thyristor Z is enabled in a case where the discharge control signal is a period (pulse width) in which the discharge control signal is lower than the power source voltage VLD. After the discharge thyristor Z is turned on once, the discharge control signal may be returned to 9 V. The pulse width W2 (width) of the discharge control signal may be shorter than the pulse width W1 (width) of the turn-on control signal. In addition, the discharge control signal may be able to turn on the discharge thyristor Z and may not change to 0 V. In a period in which the discharge control signal is lower than the power source voltage VLD, the nMOS transistor control signal for turning on the nMOS transistor 71 is turned on. In a period in which the discharge control signal is lower than the power source voltage VLD, a current flows to the nMOS transistor 71. Therefore, in a case where the discharge control signal is lower than the power source voltage VLD for a long period of time, the power consumption in the light emitting apparatus 1 increases.

The timing of the discharge control signal and the turn-on control signal is adjusted by the adjustment unit 80. In a case where the number of light emitting blocks 11 that are turned on in parallel is small, the parallel capacitance C1 is large, and the amount of charge accumulated in the parallel capacitance C1 is large. On the other hand, in a case where the number of light emitting blocks 11 that are turned on in parallel is large, the parallel capacitance C1 is small, and the amount of charge accumulated in the parallel capacitance C1 is small. Therefore, the adjustment unit 80 performs adjustment such as making the falling timing of the discharge control signal earlier than the falling timing of the turn-on control signal in a case where the number of light emitting blocks 11 that are turned on in parallel is small, and making the falling timing of the discharge control signal later than the falling timing of the turn-on control signal in a case where the number of light emitting blocks 11 that are turned on in parallel is large. The adjustment unit 80 adjusts the falling timing of the discharge control signal in accordance with the falling timing of the turn-on control signal and the number of the light emitting blocks that are turned on.

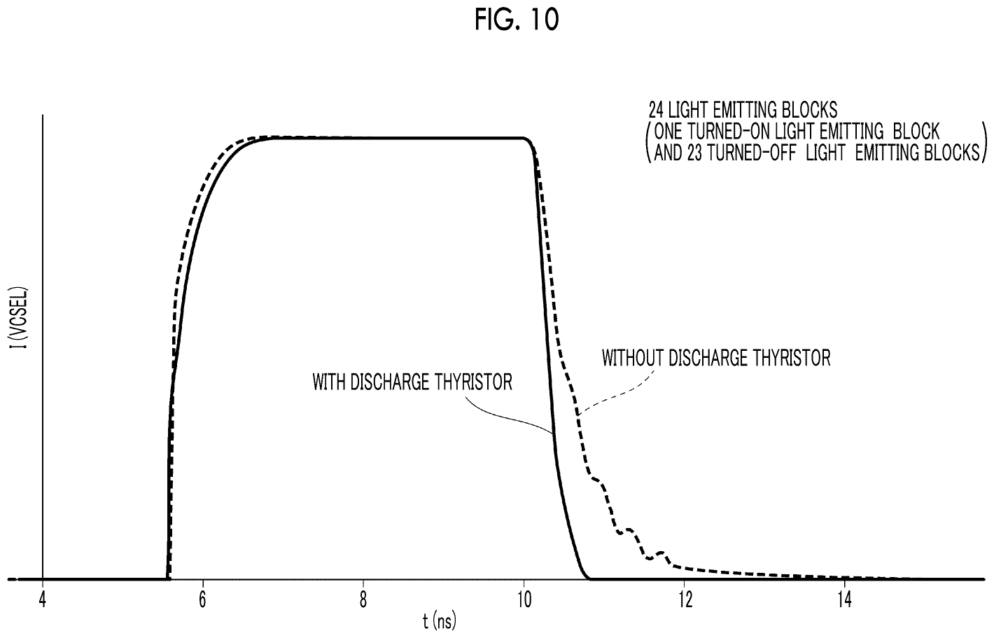

FIG. 10 shows a result of simulating a current I flowing to a VCSEL in the light emitting apparatus 1 using the light emitting device 10 including the discharge thyristor Z, to which the first exemplary embodiment is applied. The light emitting device 10 includes 24 light emitting blocks 11, one light emitting block 11 is turned on, and the other light emitting blocks 11 are turned off. In FIG. 10, the horizontal axis represents a time t (ns), and the vertical axis represents a current I (VCSEL) flowing through the VCSEL. FIG. 10 collectively shows the current I (refer to FIG. 7) flowing in the VCSEL in the light emitting apparatus 1A using the light emitting device 10A not comprising the discharge thyristor Z. The light emitting apparatus 1 using the light emitting device 10 including the discharge thyristor Z is denoted as a case of “light emitting device 10 including the discharge thyristor Z” and is denoted as “with discharge thyristor” in FIG. 10. The light emitting apparatus 1A using the light emitting device 10A that does not include the discharge thyristor Z is denoted as a case of “light emitting device 10A that does not include the discharge thyristor Z” and is denoted as “without discharge thyristor” in FIG. 10. The turn-on control signal and the discharge control signal in a case of the light emitting device 10 including the discharge thyristor Z are as shown in the timing charts of FIGS. 9A and 9B. The turn-on control signal in a case where the light emitting device 10A does not include the discharge thyristor Z is the turn-on control signal in the timing chart shown in FIG. 9A.

As shown in FIG. 10, there is little difference in the rising of the current I of the VCSEL between the case of the light emitting device 10 including the discharge thyristor Z (“with discharge thyristor”) and the case of the light emitting device 10A not including the discharge thyristor Z (“without discharge thyristor”). However, the falling of the current I of the VCSEL is smaller in a case of the light emitting device 10 including the discharge thyristor Z (“with discharge thyristor”) than in a case of the light emitting device 10A not including the discharge thyristor Z (“without discharge thyristor”). That is, by providing the discharge thyristor Z, the falling time of the current I flowing to the VCSEL is shortened. Trailing is suppressed in the light emission of the VCSEL.

As described above, in the light emitting apparatus 1, the discharge thyristor Z is turned on in a case where the light emitting block 11 is turned off. The light emitting block 11 is turned on to accumulate charges in the parallel capacitance CL. In a case where the discharge thyristor Z is turned on, the charge accumulated in the parallel capacitance C1 is discharged through the discharge path 17 configured by the discharge thyristor Z. As a result, the time constant at the time of discharge is reduced, and the time required for the current I of the VCSEL to fall is shortened. In order to reduce the time constant of the discharge, for example, the resistance R2, which is the internal resistance of the discharge thyristor Z, may be reduced.

### Light Emitting Apparatus 1C as Comparative Example

In the light emitting apparatus 1 to which the first exemplary embodiment is applied, the discharge thyristor Z is provided inside the light emitting device 10. The discharge thyristor Z constitutes a discharge path 17 that discharges the charges accumulated in the parallel capacitance C1 (Examples).

Here, as a comparative example, a light emitting device 10A including no discharge thyristors Z is used, and a light emitting apparatus 1C including a switch that configures a discharge path 18 outside the light emitting device 10A is described.

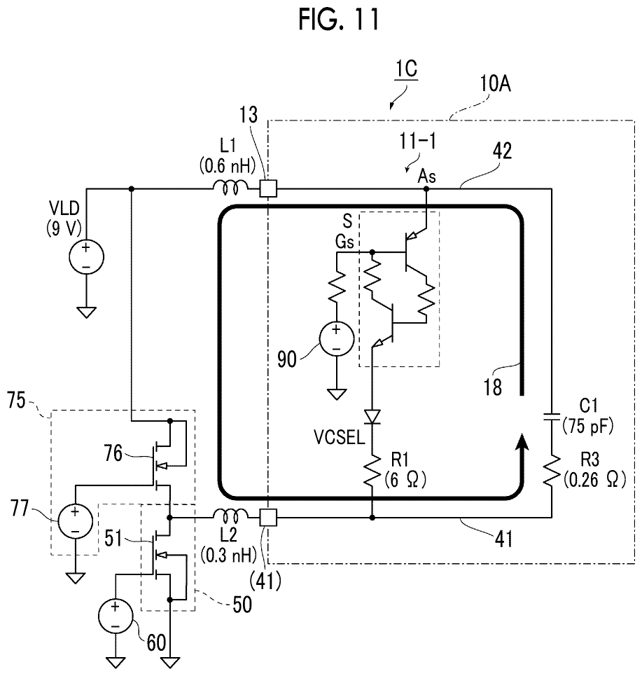

FIG. 11 shows an equivalent circuit for describing a light emitting apparatus 1C (Comparative Example) including a switch 75. The light emitting apparatus 1C includes a light emitting device 10A, the driver 50, a turn-on control unit 60, and a switch 75. The switch 75 has the same function as the discharge control unit 70 of the light emitting apparatus 1 of Example.

It is assumed that the light emitting device 10A includes 24 light emitting blocks 11 (refer to FIG. 5A). Then, one light emitting block 11 (in FIG. 11, the light emitting block 11-1) is turned on, and the other light emitting blocks 11 (the light emitting blocks 11-2 to 11-24) are turned off. The other parts are similar to FIG. 8 and will not be described using the same reference numerals.

The switch 75 includes a p-channel MOS transistor (pMOS transistor) 76 and a pMOS transistor control circuit 77. The pMOS transistor control circuit 77 supplies a signal (pMOS transistor control signal) for turning on/off the pMOS transistor 76. The drain of the pMOS transistor 76 is connected to the drain of the nMOS transistor 51 of the driver 50. The source of the pMOS transistor 76 is connected to the power source VLD. The gate of the pMOS transistor 76 is connected to a pMOS transistor control circuit 77. The pMOS transistor 76 of the switch 75 is turned off in a case where a gate voltage is equal to the power source voltage VLD, and is turned on in a case where the gate voltage is equal to or lower than a voltage obtained by subtracting the threshold voltage from the power source voltage VLD.

In a case where the nMOS transistor 51 of the driver 50 is turned on from the off state in which the switch 75 (pMOS transistor 76) is off, the light emitting block 11-1 is turned on. With the turn-on of the light emitting block 11-1, the charges are accumulated in the parallel capacitance C1. In a case where the nMOS transistor 51 of the driver 50 is turned off from the on state, the light emitting block 11-1 is turned off. In this case, in a case where the switch 75 (pMOS transistor 76) is turned on, the charge accumulated in the parallel capacitance C1 is discharged through the discharge path 18 through the switch 75 (pMOS transistor 76).

In the following simulation, the pMOS transistor control signal generated by the pMOS transistor control circuit 77 rises from 5.7 V to 9 V at 0.5 ns at a timing of 5 ns, and falls from 9 V to 5.7 V at 0.5 ns at a timing of 9.5 ns. The amplitude is 3.3 V. The pMOS transistor control signal is a pulse signal having a cycle of 40 ns. The pulse width (which may be referred to as a width) at the amplitude of 1/2 is 5 ns. The rising time/falling time is 0.5 ns. In a case where the pMOS transistor control signal is 9 V, the pMOS transistor 76 is turned off. In a case where the pMOS transistor control signal is 5.7 V, the pMOS transistor 76 is turned on.

The nMOS transistor 51 of the driver 50 is operated by the turn-on control signal shown in FIG. 9A. In this case, the nMOS transistor 51 of the driver 50 and the pMOS transistor 76 of the switch 75 are operated in a complementary manner. In other words, the pMOS transistor 76 is turned off in a case where the nMOS transistor 51 of the driver 50 is turned on, and the pMOS transistor 76 is turned on in a case where the nMOS transistor 51 of the driver 50 is turned off.

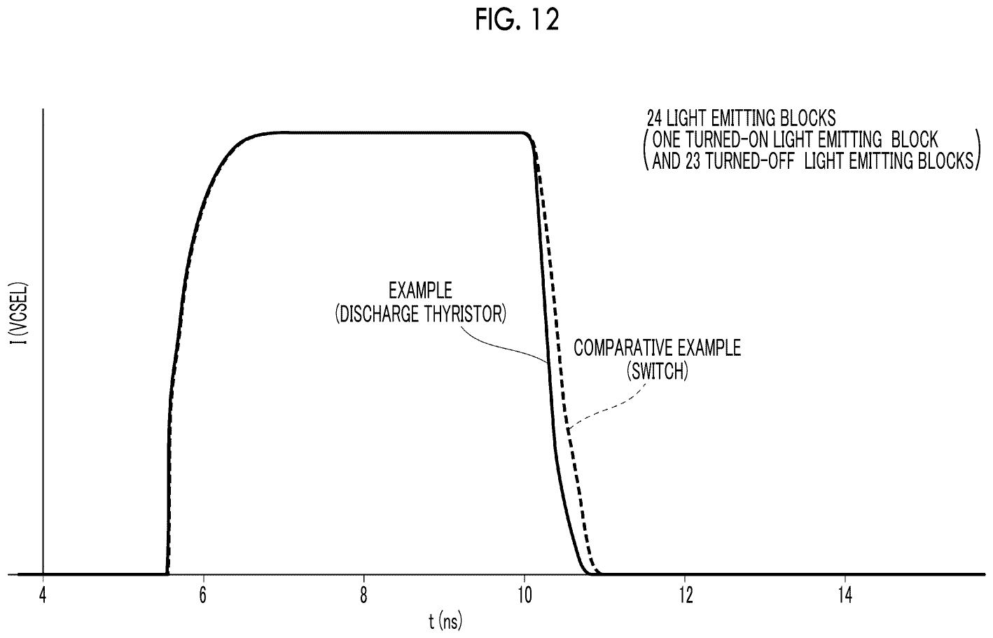

FIG. 12 shows a result of simulating a current I flowing to the VCSEL in the light emitting apparatus 1 (Example) using the light emitting device 10 including the discharge thyristor Z and the light emitting apparatus 1C (Comparative Example) including the switch 75. In the light emitting apparatus 1C (Comparative Example), the light emitting device 10A not comprising the discharge thyristor Z is used. The horizontal axis represents a time t (ns), and the vertical axis represents a current I (VCSEL) flowing through the VCSEL. In FIG. 12, the light emitting apparatus 1 using the light emitting device 10 including the discharge thyristor Z is denoted by “Example (discharge thyristor)”, and the light emitting apparatus 1C including the switch 75 is denoted by “Comparative Example (switch)”.

The rising characteristic of the current I flowing in the VCSEL is substantially the same between the light emitting apparatus 1 (Example) using the light emitting device 10 including the discharge thyristor Z and the light emitting apparatus 1C (Comparative Example) including the switch 75. On the other hand, the time for which the current I flowing in the VCSEL falls is shorter in the light emitting apparatus 1 (Example) using the light emitting device 10 including the discharge thyristor Z than in the light emitting apparatus 1C (Comparative Example) including the switch 75. In the light emitting apparatus 1C (Comparative Example) including the switch 75, the pMOS transistor 76 is provided outside the light emitting device 10A. Moreover, the pMOS transistor 76 constituting the discharge path 18 is connected to the light emitting device 10A through the parasitic inductance L2 (see FIG. 11).

On the other hand, in the light emitting apparatus 1 (Example) using the light emitting device 10 including the discharge thyristor Z, the discharge thyristor Z constituting the discharge path 17 is configured inside the light emitting device 10. Therefore, the inductance in the discharge path 17 is smaller than that in the discharge path 18 of the Comparative Example. Since the inductance is small, the falling time of the current I flowing to the VCSEL is short.

In FIG. 11, the source of the pMOS transistor 76 of the switch 75 is the power source voltage VLD (9V). In a case where the nMOS transistor 51 of the driver 50 is turned on, the voltage of the drain of the nMOS transistor 51 is set to about 1 V. Then, a voltage of about 8 V is applied between the source and the drain of the off pMOS transistor 76. The pMOS transistor 76 is required to be an element that operates at a high voltage.

As described above, as in the light emitting device 10 of the example, by forming a semiconductor device in which the light emitting block 11 and the element (here, the discharge thyristor Z) constituting the discharge path 17 are integrated, the influence of the parasitic inductance is suppressed, and the light emitting element (here, the VCSEL) has a shorter light emission falling time.

### Second Exemplary Embodiment

In the light emitting device 10 according to the first exemplary embodiment, the discharge path 17 is the discharge thyristor Z, and the discharge path 17 configured with the discharge thyristor Z is connected in parallel to the light emitting block 11. Then, as shown in FIG. 3, the n-cathode layer 35 of the discharge thyristor Z is exposed, and an n-ohmic electrode (cathode Kz) is provided.

In a light emitting device 20 in the second exemplary embodiment, it is not necessary to provide the n-ohmic electrode (cathode Kz) on the n-cathode layer 35 of the discharge thyristor Z.

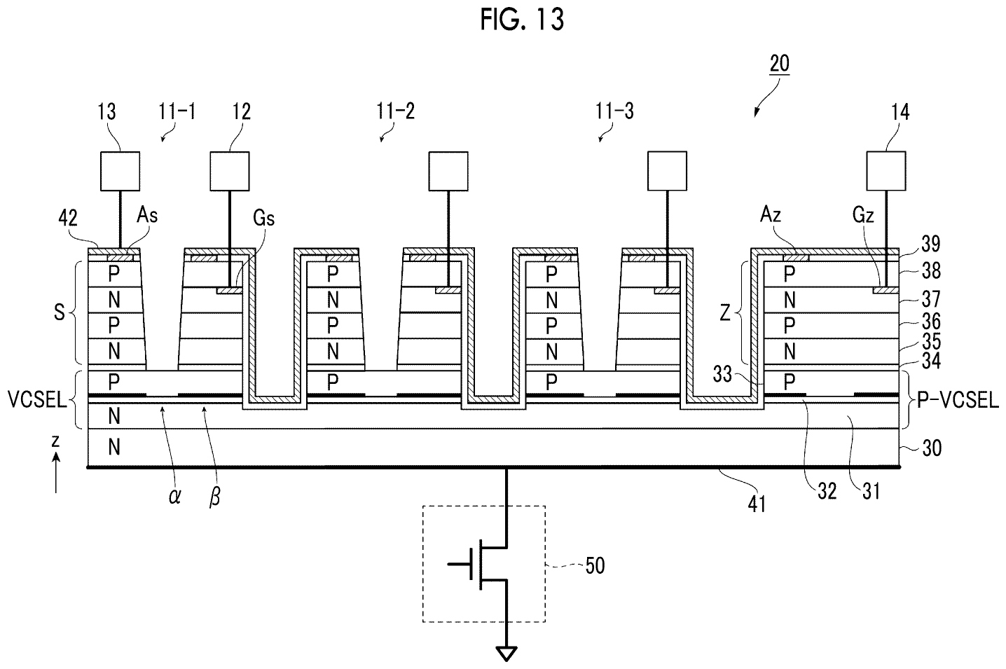

FIG. 13 is a cross-sectional view showing a cross-sectional shape of the light emitting device 20 to which the second exemplary embodiment is applied. The upward direction of the paper surface is the z direction. The similar parts to FIG. 3 are designated by the same reference numerals and will not be described.

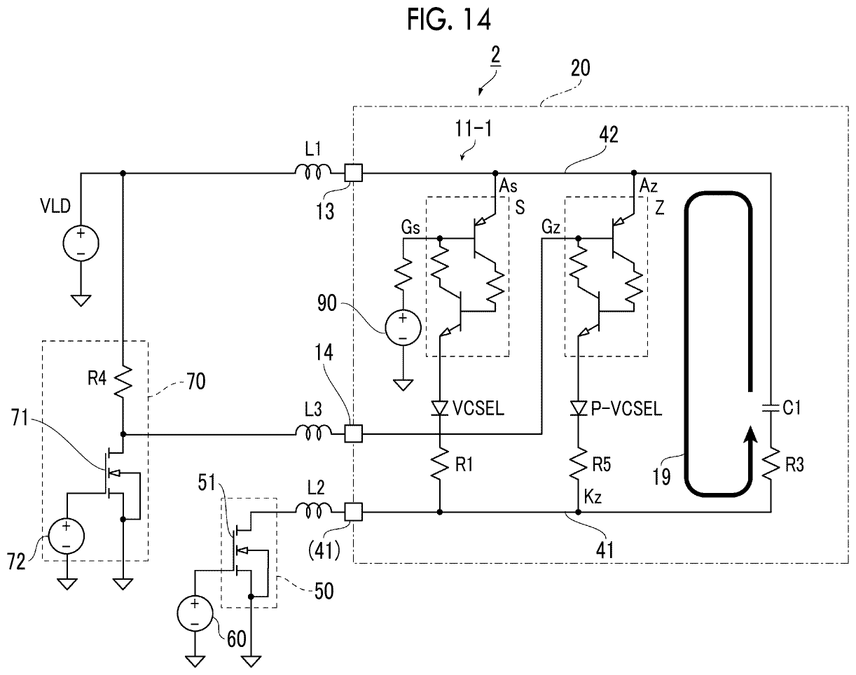

In the light emitting device 20, the discharge path 19 (refer to FIG. 14 which will be described later) is configured with a discharge thyristor Z and a pseudo VCSEL (hereinafter, referred to as P-VCSEL in FIG. 13, FIG. 14, and the following description) connected in series. The P-VCSEL is configured by the same laminated semiconductor layer as the VCSEL in the light emitting block 11. The P-VCSEL is not provided with the light emission port 43 in the light emitting block 11. The P-VCSEL is used as a diode, instead of being used as a light emitting element. In other words, the P-VCSEL is a VCSEL in the light emitting block 11, and a current flows in a case where the discharge thyristor Z connected in series is turned on. The series connection of the discharge thyristors Z and the P-VCSEL forms the discharge path 19 from the anode electrode 42 to the cathode electrode 41 (see FIG. 14 to be described later).

In the light emitting device 20, it is not necessary to provide the n-ohmic electrode (cathode Kz) on the n-cathode layer 35 of the discharge thyristor Z in the light emitting device 10 and connect the n-ohmic electrode to the cathode pad 15. That is, the step of exposing the n-cathode layer 35 of the discharge thyristor Z is not necessary. The discharge thyristor Z has the same layer configuration as the setting thyristor S of the light emitting block 11, and the P-VCSEL has the same layer configuration as the setting thyristor S of the light emitting block 11. That is, the light emitting device 20 does not require a special step for configuring the discharge path 19. In addition, the light emitting device 20 does not include the cathode pad 15 provided in the light emitting device 10. In a case where the P-VCSEL is configured by the same laminated semiconductor layer as the VCSEL in the light emitting block 11, the light emitting device 20 is easily manufactured.

The series connection of the discharge thyristor Z and the P-VCSEL forms a discharge path 19. In contrast to a case where the discharge path 17 is configured only with the discharge thyristor Z of the light emitting device 10 in the first exemplary embodiment, the internal resistance of the P-VCSEL is added to the discharge path 19. However, the internal resistance can be reduced by making the current path in the P-VCSEL thicker than that in the VCSEL in the light emitting block 11.

In a case where the discharge thyristor Z is turned on, a current flows to the P-VCSEL. In this case, in a case where a problem occurs, for example, the P-VCSEL emits light and the light is emitted to the outside through the discharge thyristor Z, a light shielding film may be provided on a path where the light is emitted by the anode electrode 42 or the like.

FIG. 14 shows an equivalent circuit of a light emitting apparatus 2 using the light emitting device 20 to which the second exemplary embodiment is applied. The same parts as those in the light emitting apparatus 1 using the light emitting device 10 in FIG. 8 will be designated by the same reference numerals and will not be described. In the light emitting device 20, the discharge path 19 is configured to be connected in series with the discharge thyristor Z and the P-VCSEL. The resistance R5 is an equivalent resistance that equivalently represents the internal resistance between the discharge thyristor Z and the P-VCSEL. The discharge thyristor Z and the P-VCSEL are connected in series to each other in parallel with the light emitting block 11 between the anode electrode 42 and the cathode electrode 41.

The light emitting apparatus 2 using the light emitting device 20 operates in the same manner as the light emitting apparatus 1 using the light emitting device 10 described in the first exemplary embodiment. The description of the light emitting apparatus 2 including the light emitting device 20 will be omitted.

Although the case where the VCSEL and the setting thyristor S are laminated in this order on the substrate 30 has been described in the light emitting device 10 to which the first exemplary embodiment is applied and the light emitting device 20 to which the second exemplary embodiment is applied, the setting thyristor S and the VCSEL may be laminated in this order on the substrate 30. In this case, the discharge thyristor Z is configured in the same manner as the setting thyristor S, and the P-VCSEL in the second exemplary embodiment may be configured in the same manner as the VCSEL. In addition, the setting thyristor S and the VCSEL may be juxtaposed on the substrate 30 without being laminated.

In the light emitting device 10 to which the first exemplary embodiment is applied and the light emitting device 20 to which the second exemplary embodiment is applied, a case where a VCSEL is used as an example of the light emitting element has been described. However, a light emitting diode (LED), a laser diode (LD), or the like may be used instead of the VCSEL. Although a case where the setting element is referred to as a setting thyristor S as an example and the discharge element is referred to as a discharge thyristor Z as an example has been described, any one or both of the setting element and the discharge element may be a transistor. The setting element and the discharge element may be configured to be integrated on a semiconductor substrate together with the light emitting element and to be capable of block irradiation.

Although the exemplary embodiments of the present invention have been described above, the technical scope of the present invention is not limited to the scope described in the above exemplary embodiments. It is apparent from the scope of the claims that exemplary embodiments with various alterations or improvements are included in the technical scope of the invention.

In addition, various modifications can be made without departing from the spirit of the present invention.

### Supplementary Notes

(((1)))

A light emitting device comprising:
a plurality of light emitting blocks, each including a light emitting element and a setting element that sets the light emitting element in a state of being able to be turned on; and
a discharge path that includes a discharge element capable of controlling discharge in a case where the light emitting element is turned off and through which charges accumulated in a case where the light emitting element is turned on are discharged,
wherein the plurality of light emitting blocks and the discharge path are electrically connected in parallel.
   (((2)))

The light emitting device according to (((1))),
wherein the discharge element is a thyristor.
   (((3)))

The light emitting device according to (((2))),
wherein the discharge path is configured by the discharge element being the thyristor,
in a light emitting block, the light emitting element is a surface emitting laser, and the setting element is a thyristor, and
the discharge path is electrically connected in parallel to a series connection of the light emitting element and the setting element.
   (((4)))

The light emitting device according to (((3))),
wherein the thyristor being the setting element and the thyristor being the discharge element include laminated semiconductor layers having an identical configuration.
   (((5)))

The light emitting device according to (((2))),
wherein the discharge path is configured by a series connection of the discharge element and a pseudo-surface emitting laser,
in the light emitting block, the light emitting element is a surface emitting laser, and the setting element is a thyristor, and
the discharge path is electrically connected in parallel to a series connection of the light emitting element and the setting element.
   (((6)))

The light emitting device according to (((5))),
wherein the thyristor being the setting element and the thyristor being the discharge element include laminated semiconductor layers having an identical configuration, and the surface emitting laser being the light emitting element and the pseudo-surface emitting laser include laminated semiconductor layers having an identical configuration.
   (((7)))

A light emitting apparatus comprising:
the light emitting device according to any one of (((1))) to (((6)));
a driver that is connected to the light emitting device and supplies a current for turning on to the light emitting element of the light emitting device;
a selection unit that selects the light emitting block to be turned on in the light emitting device and supplies a selection signal to the setting element of the selected light emitting block;
a turn-on control unit that supplies a turn-on control signal for controlling a turn-on period of the light emitting element in the light emitting device to the driver; and
a discharge control unit that supplies a discharge control signal for controlling discharge to the light emitting device.
   (((8)))

The light emitting apparatus according to (((7))),
wherein the discharge control signal starts to change to a signal voltage for turning on the discharge element, in a case where the turn-on control signal changes to a signal voltage for turning off the driver.
   (((9)))

The light emitting apparatus according to (((7))) or (((8))),
wherein a width of a signal for turning on the discharge element in the discharge control signal is smaller than a width of a signal for turning on the driver in the turn-on control signal.
   (((10)))

The light emitting apparatus according to any one of (((7))) to (((9))),
wherein a power source voltage supplied to the light emitting device is identical to a power source voltage supplied to the discharge control unit.
   (((11)))

The light emitting apparatus according to any one of (((7))) to (((10))), further comprising:
an adjustment unit that adjusts a timing at which the discharge control unit transmits a signal for turning on the discharge element in the discharge control signal, in accordance with a timing of turning off the driver in the turn-on control signal and the number of light emitting blocks that are turned on.
   (((12)))

A measuring apparatus comprising:
the light emitting apparatus according to any one of (((7))) to (((11))); and
a light receiving unit that receives light that is emitted by the light emitting apparatus and reflected from a measurement target object,
wherein the measuring apparatus measures a three-dimensional shape of the measurement target object.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting device comprising:
a plurality of light emitting blocks, each including a light emitting element and a setting element that sets the light emitting element in a state of being able to be turned on; and
a discharge path that includes a discharge element capable of controlling discharge in a case where the light emitting element is turned off and through which charges accumulated in a case where the light emitting element is turned on are discharged,
wherein the plurality of light emitting blocks and the discharge path are electrically connected in parallel.

2. The light emitting device according to claim 1,
wherein the discharge element is a thyristor.

3. The light emitting device according to claim 2,
wherein the discharge path is configured by the discharge element being the thyristor,
in a light emitting block, the light emitting element is a surface emitting laser, and the setting element is a thyristor, and
the discharge path is electrically connected in parallel to a series connection of the light emitting element and the setting element.

4. The light emitting device according to claim 3,
wherein the thyristor being the setting element and the thyristor being the discharge element include laminated semiconductor layers having an identical configuration.

5. The light emitting device according to claim 2,
wherein the discharge path is configured by a series connection of the discharge element and a pseudo-surface emitting laser,
in the light emitting block, the light emitting element is a surface emitting laser, and the setting element is a thyristor, and
the discharge path is electrically connected in parallel to a series connection of the light emitting element and the setting element.

6. The light emitting device according to claim 5,
wherein the thyristor being the setting element and the thyristor being the discharge element include laminated semiconductor layers having an identical configuration, and the surface emitting laser being the light emitting element and the pseudo-surface emitting laser include laminated semiconductor layers having an identical configuration.

7. A light emitting apparatus comprising:
the light emitting device according to claim 1;
a driver that is connected to the light emitting device and supplies a current for turning on to the light emitting element of the light emitting device;
a selection unit that selects the light emitting block to be turned on in the light emitting device and supplies a selection signal to the setting element of the selected light emitting block;
a turn-on control unit that supplies a turn-on control signal for controlling a turn-on period of the light emitting element in the light emitting device to the driver; and
a discharge control unit that supplies a discharge control signal for controlling discharge to the light emitting device.

8. The light emitting apparatus according to claim 7,
wherein the discharge control signal starts to change to a signal voltage for turning on the discharge element, in a case where the turn-on control signal changes to a signal voltage for turning off the driver.

9. The light emitting apparatus according to claim 7,
wherein a width of a signal for turning on the discharge element in the discharge control signal is smaller than a width of a signal for turning on the driver in the turn-on control signal.

10. The light emitting apparatus according to claim 7,
wherein a power source voltage supplied to the light emitting device is identical to a power source voltage supplied to the discharge control unit.

11. The light emitting apparatus according to claim 8,
wherein a power source voltage supplied to the light emitting device is identical to a power source voltage supplied to the discharge control unit.

12. The light emitting apparatus according to claim 9,
wherein a power source voltage supplied to the light emitting device is identical to a power source voltage supplied to the discharge control unit.

13. The light emitting apparatus according to claim 7, further comprising:
an adjustment unit that adjusts a timing at which the discharge control unit transmits a signal for turning on the discharge element in the discharge control signal, in accordance with a timing of turning off the driver in the turn-on control signal and the number of light emitting blocks that are turned on.

14. A measuring apparatus comprising:
the light emitting apparatus according to claim 7; and
a light receiving unit that receives light that is emitted by the light emitting apparatus and reflected from a measurement target object,
wherein the measuring apparatus measures a three-dimensional shape of the measurement target object.
